(19) United States
(12) Patent Application Publication
(10) Pub. No.: US 2026/0082924 A1
(43) Pub. Date: Mar. 19, 2026

(54) RADIATION HARDENED MEMORY CELL

(71) Applicant: Microsemi SoC Corp., Chandler, AZ (US)

(72) Inventor: Victor Nguyen, San Ramon, CA (US)

(73) Assignee: Microsemi SoC Corp., Chandler, AZ (US)

(21) Appl. No.: 18/951,354

(22) Filed: Nov. 18, 2024

Related U.S. Application Data
(60) Provisional application No. 63/695,461, filed on Sep. 17, 2024.

(51) Int. Cl. H01L 23/552; G11C 11/419; H01L 27/092; H10B 10/00

(52) U.S. Cl. CPC H10W 42/20; G11C 11/419; H10B 10/12; H10B 10/18; H10D 84/85

(57) ABSTRACT

A memory cell comprises NMOS and PMOS transistors and voltage-controlled impedance components (VCICs). A first NMOS transistor and a first PMOS transistor form a first inverter. A second NMOS transistor and a second PMOS transistor form a second inverter. The first inverter and the second inverter are electrically connected to one another to form cross-coupled inverters, wherein an input of the first inverter is coupled to an output of the second inverter and an output of the first inverter is coupled to an input of the second inverter. A first VCIC is electrically connected between the output of the first inverter and the input of the second inverter. A second VCIC is electrically connected between the input of the first inverter and the output of the second inverter. An impedance of each VCIC varies according to one or more control voltages applied to the respective VCIC.

### CROSS-REFERENCE TO RELATED APPLICATIONS

The current patent application is a non-provisional utility patent application which claims priority benefit, with regard to all common subject matter, of earlier-filed U.S. Provisional Application Ser. No. 63/695,461; titled “RADIATION HARDENED MEMORY CELL”; and filed Sep. 17, 2024. The Provisional Application is hereby incorporated by reference, in its entirety, into the current patent application.

### FIELD OF THE INVENTION

Various examples of the present technology relate to binary data storage memory cells utilizing complementary metal oxide semiconductor (CMOS) technology that are configured to maintain data integrity during a single event upset caused by electromagnetic radiation.

### BACKGROUND OF THE INVENTION

A memory cell generally stores a binary digit (bit) of data. A single event upset (SEU) is an event caused by excessive electromagnetic radiation, such as a lightning strike or other phenomenon resulting in an electric voltage or current surge to the memory cell. Often, SEUs lead to the memory cell storing a random value—which is essentially data loss. Maintaining data integrity during these events can be critical.

The background discussion is intended to provide information related to the present technology which is not necessarily prior art.

### SUMMARY OF THE INVENTION

Various examples of the present technology address the above-mentioned problem and provide a distinct advance in the art of memory cell architecture, wherein the memory cell includes voltage-controlled impedance components which increase a “hardening” of the memory cell against an SEU. A “hardened” memory cell is able to withstand the SEU and maintain a data value it had before the SEU. An example of the memory cell comprises a plurality of n-type metal oxide semiconductor (NMOS) transistors, a plurality of p-type metal oxide semiconductor (PMOS) transistors, and a plurality of voltage-controlled impedance components. A first NMOS transistor and a first PMOS transistor are electrically connected to one another to form a first inverter. A second NMOS transistor and a second PMOS transistor are electrically connected to one another to form a second inverter. The first inverter and the second inverter are electrically connected to one another to form cross-coupled inverters, wherein an input of the first inverter is coupled to an output of the second inverter and an output of the first inverter is coupled to an input of the second inverter. A first voltage-controlled impedance component is electrically connected between the output of the first inverter and the input of the second inverter. A second voltage-controlled impedance component is electrically connected between the input of the first inverter and the output of the second inverter. An impedance of each voltage-controlled impedance component varies according to one or more of a plurality of control voltages applied to the respective voltage-controlled impedance component.

Another example of the memory cell comprises a plurality of n-type metal oxide semiconductor (NMOS) transistors, a plurality of p-type metal oxide semiconductor (PMOS) transistors, and a plurality of voltage-controlled impedance components. A first NMOS transistor and a first PMOS transistor are electrically connected to one another to form a first inverter. A second NMOS transistor and a second PMOS transistor are electrically connected to one another to form a second inverter. The first inverter and the second inverter are electrically connected to one another to form cross-coupled inverters, wherein an input of the first inverter is coupled to an output of the second inverter and an output of the first inverter is coupled to an input of the second inverter. A first voltage-controlled impedance component is electrically connected between the output of the second inverter and a gate of the first NMOS transistor. A second voltage-controlled impedance component is electrically connected between the output of the first inverter and a gate of the first PMOS transistor. A third voltage-controlled impedance component is electrically connected between the output of the second inverter and a gate of the second NMOS transistor. A fourth voltage-controlled impedance component is electrically connected between the output of the first inverter and a gate of the second PMOS transistor. An impedance of each voltage-controlled impedance component varies according to one of a plurality of control voltages applied to the respective voltage-controlled impedance component.

Yet another example of the memory cell comprises a plurality of n-type metal oxide semiconductor (NMOS) transistors, a plurality of p-type metal oxide semiconductor (PMOS) transistors, and a plurality of voltage-controlled impedance components. A first NMOS transistor and a second NMOS transistor are electrically connected in series with one another, with the first NMOS transistor and the second NMOS transistor in combination forming a first pair of NMOS transistors. A first PMOS transistor and a second PMOS transistor are electrically connected in series with one another, with the first PMOS transistor and the second PMOS transistor in combination forming a first pair of PMOS transistors. The first pair of NMOS transistors and the first pair of PMOS transistors are electrically connected to one another to form a first inverter. A third NMOS transistor and a fourth NMOS transistor are electrically connected in series with one another, with the third NMOS transistor and the fourth NMOS transistor in combination forming a second pair of NMOS transistors. A third PMOS transistor and a fourth PMOS transistor are electrically connected in series with one another, with the third PMOS transistor and the fourth PMOS transistor in combination forming a second pair of PMOS transistors. The second pair of NMOS transistors and the second pair of PMOS transistors are electrically connected to one another to form a second inverter. The first inverter and the second inverter are electrically connected to one another to form cross-coupled inverters, wherein an input of the first inverter is coupled to an output of the second inverter and an output of the first inverter is coupled to an input of the second inverter. A first voltage-controlled impedance component is electrically connected between the output of the second inverter and first and second gates of the first pair of NMOS transistors. A second voltage-controlled impedance component is electrically connected between the output of the second inverter and first and second gates of the first pair of NMOS transistors. A third voltage-controlled impedance component is electrically connected between the output of the first inverter and first and second gates of the second pair of PMOS transistors. A fourth voltage-controlled impedance component is electrically connected between the output of the first inverter and first and second gates of the second pair of PMOS transistors. An impedance of each voltage-controlled impedance component varies according to one or more of a plurality of control voltages applied to the respective voltage-controlled impedance component.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the present technology will be apparent from the following detailed description of the various examples and the accompanying drawing figures.

### BRIEF DESCRIPTION OF DRAWINGS

Various examples of the present technology are described in detail below with reference to the attached drawing figures, wherein:

FIG. 1 is an electrical schematic of a memory cell constructed in accordance with at least an example of the present disclosure, the schematic depicting the electrical connections of a plurality of metal oxide semiconductor field effect transistors (MOSFETs) that form the memory cell;

FIG. 2A is a block schematic of the electric circuit components of a voltage controlled impedance component (VCIC-A);

FIG. 2B is a block schematic of the electric circuit components of a first variation of the voltage-controlled impedance component (VCIC-B);

FIG. 2C is a block schematic of the electric circuit components of a second variation of the voltage-controlled impedance component (VCIC-C);

FIG. 3 is a table listing a plurality of voltage settings for various nodes of the memory cell of FIG. 1, the voltages to be applied to the nodes during idle states, a write data process, and a read data process;

FIG. 4 is a plot of voltage vs. time for two nodes of the memory cell of FIG. 1;

FIG. 5 is an electrical schematic of another example of the memory cell;

FIG. 6 is an electrical schematic of another example of the memory cell; and

FIG. 7 is a table listing a plurality of voltage settings for various nodes of the memory cell of FIG. 6, the voltages to be applied to the nodes during idle states, a write data process, and a read data process.

The drawing figures do not limit the present technology to the specific examples disclosed and described herein. The drawings are not necessarily to scale, emphasis instead being placed upon clearly illustrating the principles of the technology.

### DETAILED DESCRIPTION OF THE INVENTION

The following detailed description of the technology references the accompanying drawings that illustrate specific examples in which the technology can be practiced. The various examples are intended to describe aspects of the technology in sufficient detail to enable those skilled in the art to practice the technology. Other examples can be utilized and changes can be made without departing from the scope of the present technology. The following detailed description is, therefore, not to be taken in a limiting sense. The scope of the present technology is defined only by the appended claims, along with the full scope of equivalents to which such claims are entitled. In addition, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

In the following description, the word “voltage” may be used to describe electric voltage, the word “current” may be used to describe electric current, and the word “power” may be used to describe electric power.

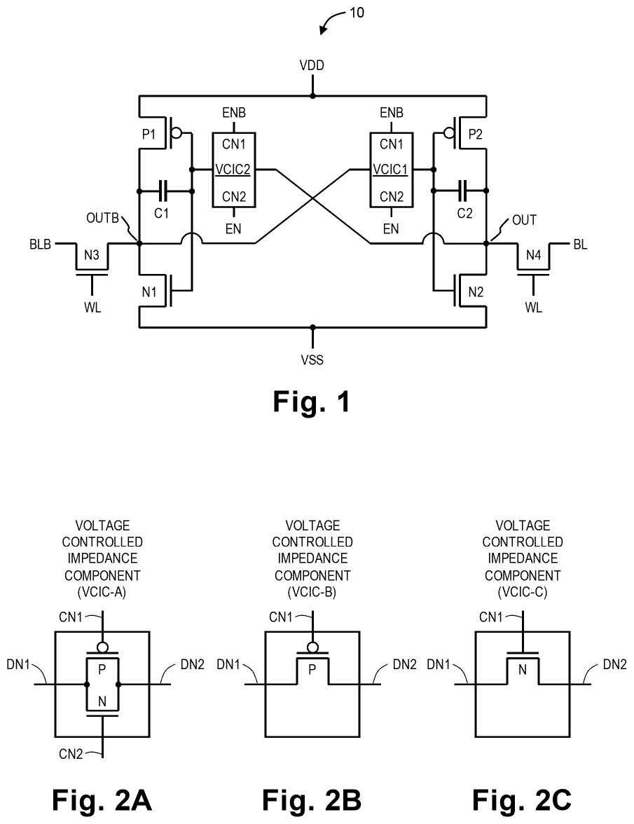

A memory cell 10, constructed in accordance with an example of the present technology, is shown in FIG. 1. The memory cell 10 provides single bit binary data storage (storing a zero “0” or a one “1”) utilizing a static random access memory (SRAM) architecture fabricated from standard process complementary metal oxide semiconductor (CMOS) technology. The memory cell 10 is also “radiation hardened”, which means it provides robust operation by maintaining its data integrity (keeping its data value) during a single event upset (SEU), such as those caused by excess radiation from an electrical power surge, a lightning strike, or the like.

The memory cell 10 may be implemented in combination with a plurality of other memory cells 10 to form a memory storage unit which can be utilized in numerous applications including configuration settings storage for a field programmable gate array (FPGA).

The memory cell 10 broadly comprises six (6) metal oxide semiconductor field effect transistors (MOSFETs) with four (4) transistors being n-type MOSFETs (NMOS), denoted N1-N4 in FIG. 1, and two (2) transistors being p-type MOSFETs (PMOS), denoted P1 and P2 in FIG. 1. Each transistor N1-N4 and P1, P2 includes a respective drain node (“drain”), a respective gate node (“gate”), and a respective source node (“source”) according to MOSFET technology. Data is read from, and written to, the memory cell 10 utilizing bit line and word line electronic signals according to memory cell technology.

The source of the first PMOS transistor P1 is electrically connected to the drain of the first NMOS transistor N1. The gate of the first PMOS transistor P1 is electrically connected to the gate of the first NMOS transistor N1. The drain of the first PMOS transistor P1 is electrically connected to a signal VDD, which is typically a voltage supply, having a voltage value ranging from approximately 0.7 Volts (V) to approximately 0.8V. The source of the first NMOS transistor N1 is electrically connected to a signal VSS, which is typically electrical ground, having a value of approximately 0V. The described configuration or architecture of the first PMOS transistor P1 and the first NMOS transistor N1 forms a first inverter having an input node (the gates of the first PMOS transistor P1 and the first NMOS transistor N1) and an output node (the source of the first PMOS transistor P1 and the drain of the first NMOS transistor N1), wherein the output node has a binary logic value that is inverted from the binary logic value of the input node. For example, if the input node has a binary logic value of zero (0), then the output node has a binary logic value of one (1), and if the input node has a binary logic value of one (1), then the output node has a binary logic value of zero (0).

The source of the second PMOS transistor P2 is electrically connected to the drain of the second NMOS transistor N2. The gate of the second PMOS transistor P2 is electrically connected to the gate of the second NMOS transistor N2. The drain of the second PMOS transistor P2 is electrically connected to VDD. The source of the second NMOS transistor N2 is electrically connected to VSS. The described configuration or architecture of the second PMOS transistor P2 and the second NMOS transistor N2 forms a second inverter having an input node (the gates of the second PMOS transistor P2 and the second NMOS transistor N2) and an output node (the source of the second PMOS transistor P2 and the drain of the second NMOS transistor N2) with the same or substantially similar performance as the first inverter. In addition, the output of the first inverter is coupled along a first feedback path to the input of the second inverter, and the output of the second inverter is coupled along a second feedback path to the input of the first inverter—which forms cross-coupled inverters that is the basis of a single-bit binary memory cell.

The third NMOS transistor N3 is electrically connected to an output bar node OUTB and a bit line bar signal BLB. The fourth NMOS transistor N4 is electrically connected to an output node OUT and a bit line signal BL. The third NMOS transistor N3 and the fourth NMOS transistor N4 are each controlled, that is, turned on and turned off, by the word line signal WL. When each transistor N3, N4 is turned on, the output bar node OUTB receives the bit line bar signal BLN, and the output node OUT receives the bit line signal BL.

The memory cell 10 further comprises two (2) voltage-controlled impedance components, denoted VCIC1 and VCIC2 in FIG. 1. In a first example shown in FIGS. 1 and 2A, each voltage-controlled impedance component includes a first data signal node DN1, a second data signal node DN2, a first control signal node CN1, and a second control signal node CN2. Each voltage-controlled impedance component VCIC1, VCIC2 further includes a PMOS transistor P and an NMOS transistor N connected in parallel with one another—that is, the drain of the PMOS transistor P is electrically connected to the drain of the NMOS transistor N and the source of the PMOS transistor P is electrically connected to the source of the NMOS transistor N. In addition, the drains of the transistors P, N are electrically connected to the first data signal node DN1, and the sources of the transistors P, N are electrically connected to the second data signal node DN2. The gate of the PMOS transistor P is electrically connected to the first control signal node CN1, and the gate of the NMOS transistor N is electrically connected to the second control node CN2.

The first and second data signal nodes DN1, DN2 are electrically connected in series with a data signal, while the first and second control signal nodes CN1, CN2 are electrically connected to first and second control signals, respectively. Typically, the control signals have complementary (logically inverted) voltage value combinations. For example, if a first control signal has a voltage value of 0.7V, then a second control signal has a voltage value of 0V—indicating a first voltage value combination. And, if the first control signal has a voltage value of 0V, then the second control signal has a voltage value of 0.7V—indicating a second voltage value combination. Each voltage-controlled impedance component has an impedance between the first data signal node DN1 and the second data signal node DN2 which varies according to the voltage value combination of the control signals. For example, the first voltage value combination for the control signals turns the transistors P, N on and may result in an impedance state which is relatively low, ranging from approximately zero (0) ohms to approximately ten (10) ohms being present between the first data signal node DN1 and the second data signal node DN2. The second voltage value combination for the control signals turns the transistors P, N off and may result in an impedance state which is relatively high, ranging from approximately one (1) megaohm to approximately one (1) gigaohm being present between the first data signal node DN1 and the second data signal node DN2. The values of the first and second voltages may vary according to, or depend on, a level of desired impedance control.

The first voltage-controlled impedance component VCIC1 is positioned along the first feedback path, with the first data signal node DN1 being electrically connected to the output of the first inverter and the second data signal node DN2 being electrically connected to the input of the second inverter. The first control signal node CN1 is electrically connected to an enable bar signal ENB, which has a voltage value ranging from approximately 0V to approximately 0.7V. The second control signal node CN2 is electrically connected to an enable signal EN, which has a voltage value ranging from approximately 0V to approximately 0.7V. The voltage values of the enable signal EN and the enable bar signal ENB are set by other circuitry in the memory storage unit in which the memory cell 10 is implemented.

The second voltage-controlled impedance component VCIC2 is positioned along the second feedback path, with the first data signal node DN1 being electrically connected to the output of the second inverter and the second data signal node DN2 being electrically connected to the input of the first inverter. The first control signal node CN1 is electrically connected to the enable bar signal ENB, and the second control signal node CN2 is electrically connected to the enable signal EN.

The first and second voltage-controlled impedance components VCIC1, VCIC2 are typically set to the low impedance state when data is being written to the memory cell, so that the voltage-controlled impedance components VCIC1, VCIC2 have minimal impact on the data storage operation. However, during idle and read data cycles, the first and second voltage-controlled impedance components VCIC1, VCIC2 are typically set to the (relatively) high impedance state which reduces feedback of the output of the cross-coupled inverters to the input to provide “hardening”of the memory cell 10 against an SEU.

In addition, the memory cell 10 includes a first capacitor C1 and a second capacitor C2. The first capacitor C1 is electrically connected in feedback from the output to the input of the first inverter. The second capacitor C2 is electrically connected in feedback from the output to the input of the second inverter. Each capacitor C1, C2 provides additional hardening of the memory cell 10 by maintaining the voltage levels of the inputs and outputs of the respective inverters, and thus, the data value, of the memory cell 10 during an SEU.

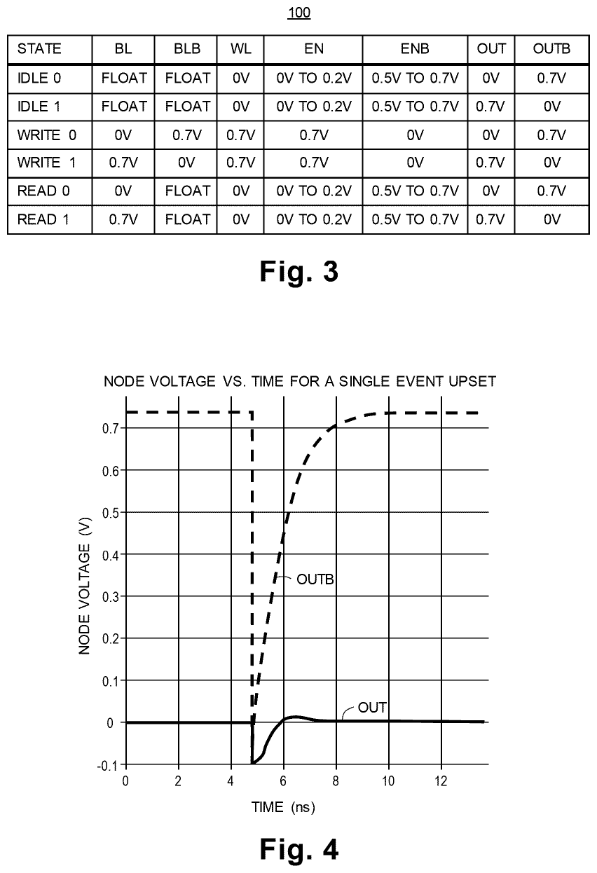

Referring to FIG. 3, a table 100 listing settings of voltage levels for various nodes of the memory cell 10 during various states including idle conditions and the write data operation is shown. The values shown are merely examples and could vary, or be tuned or adjusted—before or during operation of the memory cell 10, or both—to provide a change in impedance for the voltage-controlled impedance components. The table 100 includes columns for inputs: the bit line signal BL, the bit line bar signal BLB, the word line signal WL, the enable signal EN, and the enable bar signal ENB. The table 100 includes columns for outputs: output node OUT and output bar node OUTB. The table 100 includes rows for idle states of zero (0) and one (1), write cycles of zero (0) and one (1), and read cycles of zero (0) and one (1).

During the idle zero state, the bit line signal BL and the bit line bar signal BLB are unused, so their values may float to any voltage. The word line signal WL is held at 0V to turn off the third NMOS transistor N3 and the fourth NMOS transistor N4. The enable signal EN has a voltage ranging from 0V to 0.2V applied to the second control signal node CN2 of the two voltage-controlled impedance components VCIC1, VCIC2, and the enable bar signal ENB has a voltage ranging from 0.5V to 0.7V applied to the first control signal node CN1 of the two voltage-controlled impedance components VCIC1, VCIC2—which indicates a variation of the second voltage value combination. With the enable signal EN having a voltage of 0V and the enable bar signal having a voltage of 0.7V, each voltage-controlled impedance component VCIC1, VCIC2 has a very high impedance—nearly an open circuit, with virtually no current flowing through each voltage-controlled impedance component VCIC1, VCIC2. With the enable signal EN having a voltage of 0.2V and the enable bar signal having a voltage of 0.5V, the transistors P, N are not fully turned off (or turned on slightly) and the impedance of each voltage-controlled impedance component VCIC1, VCIC2 is reduced from (near) infinite impedance to perhaps on the order of megaohms, with a small current flowing through each voltage-controlled impedance component VCIC1, VCIC2. Since the memory cell 10 has stored a logic zero, the output node OUT has a voltage of 0V, representing logic zero, and the output bar node OUTB has a voltage of 0.7V, representing logic one.

During the idle one state, the input signals have exactly the same values as discussed above for the logic zero state. Since the memory cell 10 has stored a logic one, the output node OUT has a voltage of 0.7V, representing logic one, and the output bar node OUTB has a voltage of 0V, representing logic zero.

During the write zero cycle, the bit line signal BL has a voltage of 0V, and the bit line bar signal has a voltage of 0.7V, so that a logic zero is presented to the memory cell 10 to be written. The word line signal WL is held at 0.7V to turn on the third NMOS transistor N3 and the fourth NMOS transistor N4. The enable signal EN has a voltage of 0.7V, and the enable bar signal ENB has a voltage of 0V, which indicates the first voltage value combination and sets the impedances of the voltage-controlled impedance components VCIC1, VCIC2 to roughly zero (0) ohms so that maximum current flows through the voltage-controlled impedance components VCIC1, VCIC2. Since the memory cell 10 is storing a logic zero, the output node OUT has a voltage of 0V, representing logic zero, and the output bar node OUTB has a voltage of 0.7V, representing logic one.

During the write one cycle, the input signals have exactly the same values as discussed above for the write zero cycle, except for the bit line signal BL which has a voltage of 0.7V and the bit line bar signal BLB which has a voltage of 0V. Since the memory cell 10 is storing a logic one, the output node OUT has a voltage of 0.7V, representing logic one, and the output bar node OUTB has a voltage of 0V, representing logic zero.

During the read zero cycle, the bit line bar signal BLB is unused, so its value may float to any voltage. The bit line signal BL has a voltage of 0V since a logic zero is being read. The word line signal WL is held at 0V to turn off the third NMOS transistor N3 and the fourth NMOS transistor N4. The enable signal EN has a voltage ranging from 0V to 0.2V, and the enable bar signal ENB has a voltage ranging from 0.5V to 0.7V—indicating a variation of the second voltage value combination, as discussed above. Since the memory cell 10 has stored a logic zero, the output node OUT has a voltage of 0V, representing logic zero, and the output bar node OUTB has a voltage of 0.7V, representing logic one.

During the read one cycle, the bit line signal BL has a voltage of 0V since a logic zero is being read. The remaining input signals have the same value as discussed above for the read zero cycle. Since the memory cell 10 has stored a logic one, the output node OUT has a voltage of 0.7V, representing logic one, and the output bar node OUTB has a voltage of 0V, representing logic zero.

Referring to FIGS. 2A, 2B, and 2C, variations, or alternative examples, of the voltage-controlled impedance component discussed above, denoted as VCIC-A in FIG. 2A, are shown. In a first variation shown in FIG. 2B, the voltage-controlled impedance component VCIC-B includes just a PMOS transistor P, with the drain electrically connected to the first data signal node DN1, the source electrically connected to the second data signal node DN2, and the gate electrically connected to the first control signal node CN1. In the first variation, there is no second control signal node CN2. In a second variation shown in FIG. 2C, the voltage-controlled impedance component VCIC-C includes just an NMOS transistor N, with the drain electrically connected to the first data signal node DN1, the source electrically connected to the second data signal node DN2, and the gate electrically connected to the first control signal node CN1. In the second variation, there is no second control signal node CN2. In general, any of the variations VCIC-A, VCIC-B, or VCIC-C may be utilized when a voltage-controlled impedance component is needed in the memory cell 10. One consideration regarding which variation of the voltage-controlled impedance component to use may include availability of/access to control signals. The voltage-controlled impedance component VCIC-A requires two control signals, such as the enable signal EN and the enable bar signal ENB. The voltage-controlled impedance component VCIC-B requires one control signal, such as the enable bar signal ENB. The voltage-controlled impedance component VCIC-C requires one control signal, such as the enable signal EN. Another consideration regarding which variation of the voltage-controlled impedance component to use may include space available to place the voltage-controlled impedance component. The voltage-controlled impedance component VCIC-A is larger and requires more space than either of the voltage-controlled impedance components VCIC-B or VCIC-C.

Referring to FIG. 4, a plot of node voltage vs. time illustrates the memory cell 10 withstanding an SEU during an idle state. The memory cell 10 has stored a logic zero, so the voltage of the output bar node OUTB is approximately 0.75V, and the voltage of the output node OUT is approximately 0V. At a certain time, the memory cell 10 experiences the SEU, which has an impulse effect and briefly shifts the voltage levels of both the output bar node OUTB and the output node OUT to negative values. However, given that the voltage-controlled impedance components VCIC1, VCIC2 are in a high impedance setting, the effect of the SEU does not fully propagate through the memory cell 10. And, the voltage levels of the output bar node OUTB and the output node OUT return to their previous values—thus preserving the data stored in the memory cell 10.

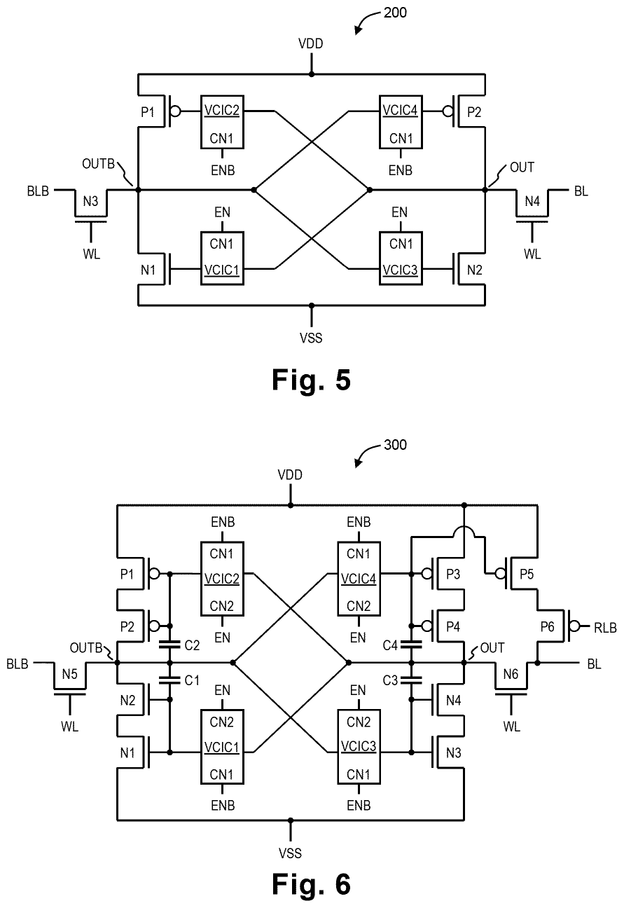

Referring to FIG. 5, a memory cell 200 is shown. The memory cell 200 is a variation of the memory cell 10 and includes the same six transistor memory cell configuration with first through fourth NMOS transistors N1-N4 and first and second PMOS transistors P1, P2 which form cross-coupled inverters. The memory cell 200 further includes two (2) voltage-controlled impedance components along each feedback path. That is, the memory cell 200 includes a first voltage-controlled impedance component VCIC1 electrically connected in series with the gate of the first NMOS transistor N1, a second voltage-controlled impedance component VCIC2 electrically connected in series with the gate of the first PMOS transistor P1, a third voltage-controlled impedance component VCIC3 electrically connected in series with the gate of the second NMOS transistor N2, and a fourth voltage-controlled impedance component VCIC4 electrically connected in series with the gate of the second PMOS transistor P2. In general, each of the voltage-controlled impedance components VCIC1-VCIC4 may be implemented as any of the variations of the voltage-controlled impedance component VCIC-A, VCIC-B, or VCIC-C. But, in the specific example shown in FIG. 5, the first and third voltage-controlled impedance components VCIC1, VCIC3 are implemented as type VCIC-C, and the second and fourth voltage-controlled impedance components VCIC2, VCIC4 are implemented as type VCIC-B. The control signal nodes of the first and third voltage-controlled impedance components VCIC1, VCIC3 are electrically connected to the enable signal EN, and the control signal nodes of the second and fourth voltage-controlled impedance components VCIC2, VCIC4 are electrically connected to the enable bar signal ENB.

The third NMOS transistor N3 is electrically connected to an output bar node OUTB and a bit line bar signal BLB. The fourth NMOS transistor N4 is electrically connected to an output node OUT and a bit line signal BL. The third NMOS transistor N3 and the fourth NMOS transistor N4 are each controlled, that is, turned on and turned off, by the word line signal WL. When each transistor N3, N4 is turned on, the output bar node OUTB receives the bit line bar signal BLN, and the output node OUT receives the bit line signal BL.

The memory cell 200 operates in a substantially similar manner as the memory cell 10, with the first and second voltage-controlled impedance components VCIC1, VCIC2, in combination, performing in a similar manner as the first voltage-controlled impedance component VCIC1, and the third and fourth voltage-controlled impedance components VCIC3, VCIC4, in combination, performing in a similar manner as the second voltage-controlled impedance component VCIC2. In addition, the settings of the voltage levels at various nodes of the memory cell 200 follows the same settings as are listed in the table 100 of FIG. 3.

As compared to the memory cell 10, the memory cell 200 may provide more selective hardening in that the impedance along the feedback path to each transistor of the cross-coupled inverters can be controlled.

Referring to FIG. 6, a memory cell 300 is shown. The memory cell 300 is a variation of the memory cell 10 and the memory cell 200. The memory cell 300 includes first through fourth NMOS transistors N1-N4 and first through fourth PMOS transistors P1-P4. The first and second NMOS transistors N1, N2 are electrically connected in series, with the drain of the first electrically connected to the source of the second. In addition, the gate of the first NMOS transistor N1 is electrically connected to the gate of the second NMOS transistor N2. In combination, the first and second NMOS transistors N1, N2 form a first pair of NMOS transistors. The first and second PMOS transistors P1, P2 are electrically connected in series, with the source of the first electrically connected to the drain of the second. In addition, the gate of the first PMOS transistor P1 is electrically connected to the gate of the second PMOS transistor P2. In combination, the first and second PMOS transistors P1, P2 form a first pair of PMOS transistors. The drain of the first PMOS transistor P1 is electrically connected to VDD. The source of the first NMOS transistor N1 is electrically connected to VSS. Accordingly, the first pair of PMOS transistors and the first pair of NMOS transistors form a first inverter.

The third and fourth NMOS transistors N3, N4 are electrically connected in series, with the drain of the third electrically connected to the source of the fourth. In addition, the gate of the third NMOS transistor N3 is electrically connected to the gate of the fourth NMOS transistor N4. In addition, the gate of the third NMOS transistor N3 is electrically connected to the gate of the fourth NMOS transistor N4. In combination, the third and fourth NMOS transistors N3, N4 form a second pair of NMOS transistors. The third and fourth PMOS transistors P3, P4 are electrically connected in series, with the source of the third electrically connected to the drain of the fourth. In addition, the gate of the third PMOS transistor P3 is electrically connected to the gate of the fourth PMOS transistor P4. In addition, the gate of the third PMOS transistor P3 is electrically connected to the gate of the fourth PMOS transistor P4. In combination, the third and fourth PMOS transistors P3, P4 form a second pair of PMOS transistors. The drain of the third PMOS transistor P3 is electrically connected to VDD. The source of the third NMOS transistor N3 is electrically connected to VSS. Accordingly, the second pair of PMOS transistors and the second pair of NMOS transistors form a second inverter. The output of the first inverter is coupled to the input of the second inverter, and the output of the second inverter is coupled to the input of the first inverter—forming a cross-coupled inverter data storage cell.

The memory cell 300 further includes first through fourth voltage-controlled impedance components VCIC1-VCIC4, electrically connected in the same, or similar, fashion as the first through fourth voltage-controlled impedance components VCIC1-VCIC4 of the memory cell 200. The first voltage-controlled impedance component VCIC1 is electrically connected in series with the gates of the first pair of NMOS transistors. The second voltage-controlled impedance component VCIC2 is electrically connected in series with the gates of the first pair of PMOS transistors. The third voltage-controlled impedance component VCIC3 is electrically connected in series with the gates of the second pair of NMOS transistors. The fourth voltage-controlled impedance component VCIC4 is electrically connected in series with the gates of the second pair of PMOS transistors. In general, each of the voltage-controlled impedance components VCIC1-VCIC4 may be implemented as any of the variations of the voltage-controlled impedance component VCIC-A, VCIC-B, or VCIC-C. But, in the specific example shown in FIG. 6, each of the voltage-controlled impedance components VCIC1-VCIC4 is implemented as a VCIC-A type.

The memory cell 300 also includes fifth and sixth NMOS transistors N5, N6. The fifth NMOS transistor N5 is electrically connected to an output bar node OUTB and a bit line bar signal BLB. The sixth NMOS transistor N6 is electrically connected to an output node OUT and a bit line signal BL. The fifth NMOS transistor N5 and the sixth NMOS transistor N6 are each controlled, that is, turned on and turned off, by the word line signal WL. When each transistor N5, N6 is turned on, the output bar node OUTB receives the bit line bar signal BLN, and the output node OUT receives the bit line signal BL.

In addition, the memory cell 300 includes first through fourth capacitors C1-C4. Capacitor C1 is electrically connected between the output node OUTB and the gates of the first pair of NMOS transistors. Capacitor C2 is electrically connected between the output node OUTB and the gates of the first pair of PMOS transistors. Capacitor C3 is electrically connected between the output node OUT and the gates of the second pair of NMOS transistors. Capacitor C4 is electrically connected between the output node OUT and the gates of the second pair of PMOS transistors.

The memory cell 300 additionally includes a fifth PMOS transistor P5 and a sixth PMOS transistor P6 that are electrically connected in series with one another between the VDD node and the bit line BL node. The gate of the fifth PMOS transistor P5 is electrically connected to the gates of the third and fourth PMOS transistors P3, P4, and the gate of the sixth PMOS transistor P6 is electrically connected to a read line bar RLB signal. The addition of transistors (so that each inverter operates with two pairs of transistors instead of two individual transistors) and the addition of capacitors coupling output nodes to inputs further “hardens” the memory cell 300 by maintaining the voltage levels of the inputs and outputs of the respective inverters, and thus, the data value, of the memory cell 300 during an SEU.

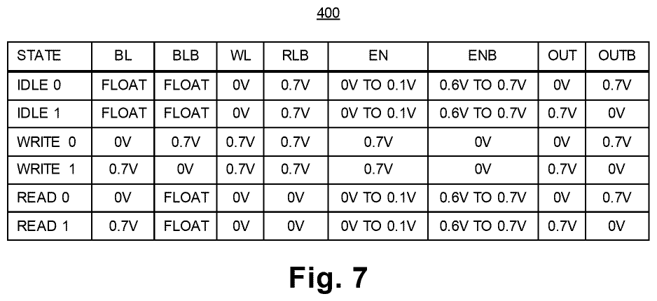

Referring to FIG. 7, a table 400 lists settings of voltage levels for various nodes of the memory cell 300 during various states including idle conditions and the write data operation is shown. The values shown are merely examples and could vary, or be tuned or adjusted—before or during operation of the memory cell 300, or both—to provide a change in impedance for the voltage-controlled impedance components. The table 400 includes columns for inputs: the bit line signal BL, the bit line bar signal BLB, the word line signal WL, the read line bar signal RLB, the enable signal EN, and the enable bar signal ENB. The table 400 includes columns for outputs: output node OUT and output bar node OUTB. The table 100 includes rows for idle states of zero (0) and one (1), write cycles of zero (0) and one (1), and read cycles of zero (0) and one (1).

During the idle zero state, the bit line signal BL and the bit line bar signal BLB are unused, so their values may float to any voltage. The word line signal WL is held at 0V to turn off the fifth NMOS transistor N5 and the sixth NMOS transistor N6. The read line bar signal RLB has a voltage of 0.7V to turn off the sixth PMOS transistor P6. The enable signal EN has a voltage ranging from 0V to 0.1V applied to the second control signal node CN2 of the four voltage-controlled impedance components VCIC1-VCIC4, and the enable bar signal ENB has a voltage ranging from 0.6V to 0.7V applied to the first control signal node CN1 of the four voltage-controlled impedance components VCIC1-VCIC4—which indicates a variation of the second voltage value combination described above. With the enable signal EN having a voltage of 0V and the enable bar signal having a voltage of 0.7V, each voltage-controlled impedance component VCIC1-VCIC4 has a very high impedance—nearly an open circuit, with virtually no current flowing through each voltage-controlled impedance component VCIC1-VCIC4. With the enable signal EN having a voltage of 0.1V and the enable bar signal having a voltage of 0.6V, the transistors P, N are not fully turned off (or turned on slightly) and the impedance of each voltage-controlled impedance component VCIC1-VCIC4 is reduced from (near) infinite impedance to perhaps on the order of megaohms, with a small current flowing through each voltage-controlled impedance component VCIC1-VCIC4. Since the memory cell 300 has stored a logic zero, the output node OUT has a voltage of 0V, representing logic zero, and the output bar node OUTB has a voltage of 0.7V, representing logic one.

During the idle one state, the input signals have exactly the same values as discussed above for the logic zero state. Since the memory cell 300 has stored a logic one, the output node OUT has a voltage of 0.7V, representing logic one, and the output bar node OUTB has a voltage of 0V, representing logic zero.

During the write zero cycle, the bit line signal BL has a voltage of 0V, and the bit line bar signal has a voltage of 0.7V, so that a logic zero is presented to the memory cell 300 to be written. The word line signal WL is held at 0.7V to turn on the fifth NMOS transistor N5 and the sixth NMOS transistor N6. The read line bar signal RLB has a voltage of 0.7V to turn off the sixth PMOS transistor P6. The enable signal EN has a voltage of 0.7V, and the enable bar signal ENB has a voltage of 0V, which sets the impedances of the voltage-controlled impedance components VCIC1-VCIC4 to roughly zero (0) ohms so that maximum current flows through the voltage-controlled impedance components VCIC1-VCIC4. Since the memory cell 300 is storing a logic zero, the output node OUT has a voltage of 0V, representing logic zero, and the output bar node OUTB has a voltage of 0.7V, representing logic one.

During the write one cycle, the input signals have exactly the same values as discussed above for the write zero cycle, except for the bit line signal BL which has a voltage of 0.7V and the bit line bar signal BLB which has a voltage of 0V. Since the memory cell 300 is storing a logic one, the output node OUT has a voltage of 0.7V, representing logic one, and the output bar node OUTB has a voltage of 0V, representing logic zero.

During the read zero cycle, the bit line bar signal BLB is unused, so its value may float to any voltage. The bit line signal BL has a voltage of 0V since a logic zero is being read. The word line signal WL is held at 0V to turn off the fifth NMOS transistor N5 and the sixth NMOS transistor N6. The read line bar signal RLB has a voltage of 0V to turn on the sixth PMOS transistor P6. The enable signal EN has a voltage ranging from 0V to 0.1V, and the enable bar signal ENB has a voltage ranging from 0.6V to 0.7V, as discussed above. Since the memory cell 300 has stored a logic zero, the output node OUT has a voltage of 0V, representing logic zero, and the output bar node OUTB has a voltage of 0.7V, representing logic one.

During the read one cycle, the bit line signal BL has a voltage of 0V since a logic zero is being read. The remaining input signals have the same value as discussed above for the read zero cycle. Since the memory cell 300 has stored a logic one, the output node OUT has a voltage of 0.7V, representing logic one, and the output bar node OUTB has a voltage of 0V, representing logic zero.

Throughout this specification, references to “one example”, “an example”, or “examples” mean that the feature or features being referred to are included in at least one example of the technology. Separate references to “one example”, “an example”, or “examples” in this description do not necessarily refer to the same example and are also not mutually exclusive unless so stated and/or except as will be readily apparent to those skilled in the art from the description. For example, a feature, structure, act, etc. described in one example may also be included in other examples, but is not necessarily included. Thus, the present technology can include a variety of combinations and/or integrations of the examples described herein.

Although the present application sets forth a detailed description of numerous different examples, it should be understood that the legal scope of the description is defined by the words of the claims set forth at the end of this patent and equivalents. The detailed description is to be construed as illustrative only and does not describe each possible example since describing each possible example would be impractical. Numerous alternative examples may be implemented, using either present technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the examples illustrated in the attached drawing figures, it is noted that equivalents may be employed and substitutions made herein without departing from the scope of the technology as recited in the claims.

Having thus described various examples of the technology, what is claimed as new and desired to be protected by Letters Patent includes the following:

1. A memory cell comprising:
a first n-type metal oxide semiconductor (NMOS) transistor and a first p-type metal oxide semiconductor (PMOS) transistor electrically connected to one another to form a first inverter;
a second NMOS transistor and a second PMOS transistor electrically connected to one another to form a second inverter, the first inverter and the second inverter electrically connected to one another to form cross-coupled inverters, wherein an input of the first inverter is coupled to an output of the second inverter and an output of the first inverter is coupled to an input of the second inverter;
a first voltage-controlled impedance component electrically connected between the output of the first inverter and the input of the second inverter; and
a second voltage-controlled impedance component electrically connected between the input of the first inverter and the output of the second inverter,
wherein an impedance of each voltage-controlled impedance component varies according to one or more of a plurality of control voltages applied to the respective voltage-controlled impedance component.

2. The memory cell of claim 1, wherein the first voltage-controlled impedance component includes a first transmission gate and the second voltage-controlled impedance component includes a second transmission gate.

3. The memory cell of claim 2, wherein the first voltage-controlled impedance component and the second voltage-controlled impedance component each include a first control node to which a first control voltage is applied and a second control node to which a second control voltage is applied.

4. The memory cell of claim 3, wherein, during a first state, the first control voltage has a value ranging from approximately zero Volts to approximately 0.2 Volts and the second control voltage has a value ranging from approximately 0.5 Volts to approximately 0.7 Volts.

5. The memory cell of claim 4, wherein, during a second state, the first control voltage has a value of approximately 0.7 Volts and the second control voltage has a value of approximately zero Volts.

6. The memory cell of claim 1, further comprising
a third NMOS transistor including a source electrically connected to the output of the first inverter, a drain electrically connected to a bit line bar electronic signal, and a gate electrically connected to a write line electronic signal; and
a fourth NMOS transistor including a source electrically connected to the output of the second inverter, a drain electrically connected to a bit line electronic signal, and a gate electrically connected to the write line electronic signal.

7. The memory cell of claim 1, further comprising
a first capacitor electrically connected between the output of the first inverter and the input of the first inverter; and
a second capacitor electrically connected between the output of the second inverter and the input of the second inverter.

8. A memory cell comprising:
a first n-type metal oxide semiconductor (NMOS) transistor and a first p-type metal oxide semiconductor (PMOS) transistor electrically connected to one another to form a first inverter;
a second NMOS transistor and a second PMOS transistor electrically connected to one another to form a second inverter, the first inverter and the second inverter electrically connected to one another to form cross-coupled inverters, wherein an input of the first inverter is coupled to an output of the second inverter and an output of the first inverter is coupled to an input of the second inverter;
a first voltage-controlled impedance component electrically connected between the output of the second inverter and a gate of the first NMOS transistor;
a second voltage-controlled impedance component electrically connected between the output of the first inverter and a gate of the first PMOS transistor;
a third voltage-controlled impedance component electrically connected between the output of the second inverter and a gate of the second NMOS transistor; and
a fourth voltage-controlled impedance component electrically connected between the output of the first inverter and a gate of the second PMOS transistor,
wherein an impedance of each voltage-controlled impedance component varies according to one of a plurality of control voltages applied to the respective voltage-controlled impedance component.

9. The memory cell of claim 8, wherein
the first voltage-controlled impedance component includes a third NMOS transistor;
the second voltage-controlled impedance component includes a third PMOS transistor;
the third voltage-controlled impedance component includes a fourth NMOS transistor; and
the fourth voltage-controlled impedance component includes a fourth PMOS transistor.

10. The memory cell of claim 9, wherein
the first voltage-controlled impedance component and the third voltage-controlled impedance component each include a first control node to which a first control voltage is applied, and
the second voltage-controlled impedance component and the fourth voltage-controlled impedance component each include a second control node to which a second control voltage is applied.

11. The memory cell of claim 10, wherein, during a first state, the first control voltage has a value ranging from approximately zero Volts to approximately 0.2 Volts and the second control voltage has a value ranging from approximately 0.5 Volts to approximately 0.7 Volts.

12. The memory cell of claim 11, wherein, during a second state, the first control voltage has a value of approximately 0.7 Volts and the second control voltage has a value of approximately zero Volts.

13. The memory cell of claim 12, further comprising a third NMOS transistor including a source electrically connected to the output of the first
inverter, a drain electrically connected to a bit line bar electronic signal, and a gate electrically connected to a write line electronic signal; and
a fourth NMOS transistor including a source electrically connected to the output of the second inverter, a drain electrically connected to a bit line electronic signal, and a gate electrically connected to the write line electronic signal.

14. A memory cell comprising:
a first n-type metal oxide semiconductor (NMOS) transistor and a second NMOS transistor electrically connected in series with one another, the first NMOS transistor and the second NMOS transistor in combination forming a first pair of NMOS transistors;
a first p-type metal oxide semiconductor (PMOS) transistor and a second PMOS transistor electrically connected in series with one another, the first PMOS transistor and the second PMOS transistor in combination forming a first pair of PMOS transistors, the first pair of NMOS transistors and the first pair of PMOS transistors electrically connected to one another to form a first inverter;
a third NMOS transistor and a fourth NMOS transistor electrically connected in series with one another, the third NMOS transistor and the fourth NMOS transistor in combination forming a second pair of NMOS transistors;
a third PMOS transistor and a fourth PMOS transistor electrically connected in series with one another, the third PMOS transistor and the fourth PMOS transistor in combination forming a second pair of PMOS transistors, the second pair of NMOS transistors and the second pair of PMOS transistors electrically connected to one another to form a second inverter, the first inverter and the second inverter electrically connected to one another to form cross-coupled inverters, wherein an input of the first inverter is coupled to an output of the second inverter and an output of the first inverter is coupled to an input of the second inverter;
a first voltage-controlled impedance component electrically connected between the output of the second inverter and first and second gates of the first pair of NMOS transistors;
a second voltage-controlled impedance component electrically connected between the output of the second inverter and first and second gates of the first pair of NMOS transistors;
a third voltage-controlled impedance component electrically connected between the output of the first inverter and first and second gates of the second pair of PMOS transistors; and
a fourth voltage-controlled impedance component electrically connected between the output of the first inverter and first and second gates of the second pair of PMOS transistors,
wherein an impedance of each voltage-controlled impedance component varies according to one or more of a plurality of control voltages applied to the respective voltage-controlled impedance component.

15. The memory cell of claim 14, wherein
the first voltage-controlled impedance component includes a first transmission gate;
the second voltage-controlled impedance component includes a second transmission gate;
the third voltage-controlled impedance component includes a third transmission gate; and
the fourth voltage-controlled impedance component includes a fourth transmission gate.

16. The memory cell of claim 15, wherein the first voltage-controlled impedance component, the second voltage-controlled impedance component, the third voltage-controlled impedance component, and the fourth voltage-controlled impedance component each include a first control node to which a first control voltage is applied and a second control node to which a second control voltage is applied.

17. The memory cell of claim 16, wherein, during a first state, the first control voltage has a value ranging from approximately zero Volts to approximately 0.1 Volts and the second control voltage has a value ranging from approximately 0.6 Volts to approximately 0.7 Volts.

18. The memory cell of claim 17, wherein, during a second state, the first control voltage has a value of approximately 0.7 Volts and the second control voltage has a value of approximately zero Volts.

19. The memory cell of claim 14, further comprising
a fifth NMOS transistor including a source electrically connected to the output of the first inverter, a drain electrically connected to a bit line bar electronic signal, and a gate electrically connected to a write line electronic signal; and
a sixth NMOS transistor including a source electrically connected to the output of the second inverter, a drain electrically connected to a bit line electronic signal, and a gate electrically connected to the write line electronic signal.

20. The memory cell of claim 14, further comprising
a fifth PMOS transistor including a drain electrically connected to a drain of the first PMOS transistor and a drain of the third PMOS transistor and a gate electrically connected to a gate of the third PMOS transistor and a gate of the fourth PMOS transistor; and
a sixth PMOS transistor including a drain electrically connected to a source of the fifth PMOS transistor, a source electrically connected to a bit line electronic signal, and a gate electrically connected to a read line bar electronic signal.
